(19) United States
(12) Patent Application Publication
(10) Pub. No.: US 2026/0351320 A1
(43) Pub. Date: Nov. 5, 2026

(54) READ THRESHOLD MANAGEMENT USING ONLINE LEARNING ALGORITHM

(71) Applicant: Micron Technology, Inc., Boise, ID (US)

(72) Inventors: Zixiang Loh, San Jose, CA (US); Steven Michael Kientz, Westminster, CO (US)

(21) Appl. No.: 19/195,089

(22) Filed: Apr. 30, 2025

(51) Int. Cl. G11C 16/34; G06F 17/16; G11C 16/26

(52) U.S. Cl. CPC G11C 16/3404; G06F 17/16; G11C 16/26

(57) ABSTRACT

A processing device obtains initial weight values for a memory device. The processing device periodically calculates predicted values for a target read voltage level for a portion of the memory device based on the initial weight values. The calculating of the predicted values comprises calculating a predicted value for the target read voltage level based on the initial weight values and a first measured value for a reference read voltage level of the portion of the memory device. The processing device periodically updates the weight values for the portion of the memory device. The updating of the weight values comprises determining updated weight values for the portion of the memory device based on the initial weight values, a measured value for the target read voltage level, a second measured value for the reference read voltage level, and the predicted value for the target read voltage level.

### TECHNICAL FIELD

Embodiments of the disclosure relate generally to memory sub-systems and, more specifically, to techniques for read threshold management for memory sub-systems.

### BACKGROUND

A memory sub-system can be a storage system, such as a solid-state drive (SSD), and can include one or more memory components that store data. The memory components can be, for example, memory devices that include non-volatile memory components and/or volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system, in accordance with some examples.

FIGS. 2A and 2B are conceptual diagrams illustrating an example process for read threshold management of a memory device, in accordance with some examples.

FIGS. 3-5 are flow diagrams illustrating an example method for performing read threshold management on a memory device, in accordance with some examples.

FIG. 6 is a block diagram of an example computer system in which embodiments of the present disclosure may operate.

### DETAILED DESCRIPTION

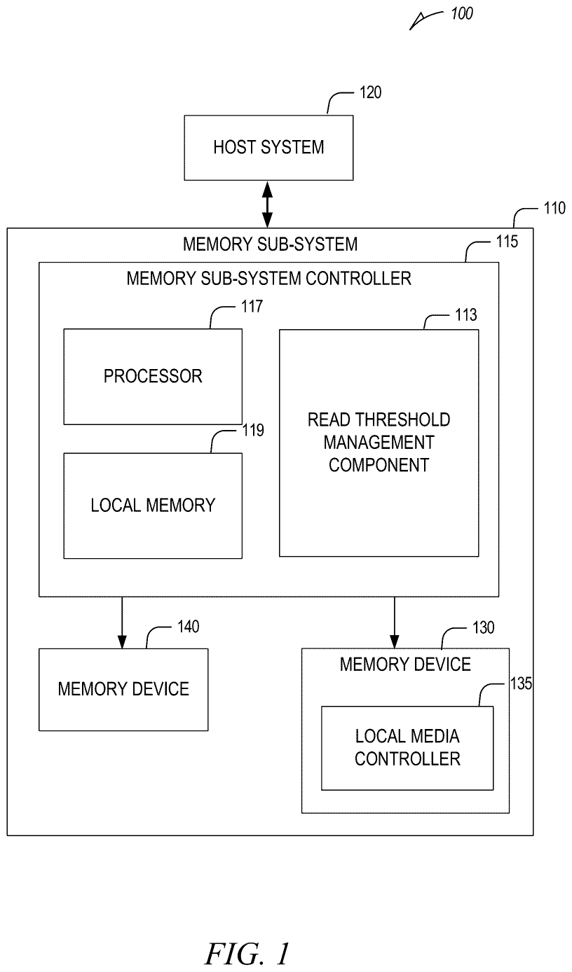

Aspects of the present disclosure are directed to an approach for performing read threshold management of a memory device in a memory sub-system using an in-field online learning algorithm. A memory sub-system can be or include a memory device (e.g., solid-state drive [SSD]), a memory module, or a combination of a memory device and memory module. Examples of memory devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system. A memory sub-system controller typically receives commands or operations from the host system and converts the commands or operations into instructions or appropriate commands to achieve the desired access to the memory components of the memory sub-system.

A memory device can be a non-volatile memory device. One example of a non-volatile memory device is a negative-and (NAND) memory device. A NAND memory device can include multiple NAND dies. Each die may include one or more planes, and each plane includes multiple blocks. Each block includes an array that includes pages (rows) and strings (columns). Pages may be organized into multiple groups such as word line groups (also referred to as “word line clusters”). A string includes a plurality of memory cells connected in series. A memory cell (also referred to herein simply as a “cell”) is an electronic circuit (e.g., including a transistor) that stores information. Depending on the cell type, a cell can store one or more bits of binary information and has various logic states that correlate to the number of bits being stored. The logic states can be represented by binary values, such as “0” and “1,” or combinations of such values.

Various memory access operations can be performed on the memory cells. Data can be written to, read from, and erased from memory cells. Memory cells can be grouped into a write unit, such as a page. For some types of memory devices, a page is the smallest write unit. Data can be written to a block, page-by-page. During write operations, data is programmed into a block of the memory device using a programming sequence that includes multiple passes in which programming pulses are applied to cells in the block. Over the multiple passes, the programming pulses configure the threshold voltages (V_{T}) of the cells in each page according to the value that the cells are intended to represent. As the programming sequence progresses, the voltage level of the programming pulses increase until a target voltage level for each cell is reached.

The V_{T} distribution of a memory cell can be divided into a number of regions based on the number of bits stored by the cell where each region corresponds to a value that can be represented by the cell. More specifically, each region corresponds to a read voltage level (also referred to as a “read level”), and each read voltage level decodes into a multi-bit value. For example, a triple level cell (TLC) NAND flash cell can be at one of eight read voltage levels (e.g., L0, L1, L2, L3, L4, L5, L6, or L7) and each read voltage level decodes into a 3-bit value that is stored in the flash cell (e.g., 111, 110, 100, 000, 010, 011, 001, and 101). Generally, to read data from a memory cell, one or more read threshold voltages are applied to the gate of a transistor (of the memory cell) to determine (e.g., sense) the value of the current V_{T} (e.g., the voltage at which the transistor conducts current), and the current V_{T} value can be decoded (e.g., mapped) to a data value (e.g., bit string) stored by the memory cell.

As NAND devices cycle through program and erase operations, the charge stored in memory cells gradually decreases due to charge loss effects, causing shifts in the V_{T} distributions. This charge loss behavior presents particular challenges in multi-level cell configurations such as TLC devices, where eight distinct voltage levels must be precisely maintained to store three bits per cell. The voltage distributions for these levels tend to shift over time as charge is lost, requiring ongoing adjustment of read threshold voltages.

Current read threshold management approaches rely on lookup tables that store predefined offset values based on measured correlations between read levels. These tables are typically generated by characterizing the behavior of multiple dies during manufacturing and calculating average responses.

However, significant variations exist both between individual dies (die-to-die variation) and across different program-erase cycle (PEC) counts (PEC variation). These variations mean that any single lookup table represents only an approximate average behavior rather than the specific characteristics of individual dies.

The challenge of managing these variations becomes particularly acute in large-scale storage systems that may contain dozens of dies. Each die exhibits slightly different behavioral characteristics in terms of charge loss and level-to-level correlations. Additionally, as devices age and undergo more program-erase cycles, these behavioral characteristics continue to evolve.

Traditional approaches attempt to address these variations by creating multiple lookup tables to handle different operating conditions. However, this requires significant memory overhead that increases with the number of dies in the system. The discrete nature of lookup tables also presents challenges in handling the continuous changes that occur during device operation. Furthermore, comprehensive characterization of individual die behavior during manufacturing is time-consuming and costly, yet may still not fully capture how each die will behave across its operational lifetime.

Aspects of the present disclosure address the above and other issues with a memory sub-system that utilizes an online learning algorithm for read threshold management to continuously adapt to changing device characteristics while accounting for die-to-die and PEC variations. The algorithm maintains weight parameters for each die in the memory device. These weight parameters form a two-dimensional matrix used to calculate appropriate read threshold voltages without requiring lookup tables.

During operation, a read threshold management component of the memory sub-system periodically measures read levels (voltage levels) across different dies. At fixed time intervals T, the read threshold management component collects measurement pairs between voltage levels. Each measurements pair captures both a reference level (such as L7) and a target level that requires threshold adjustment. The weight parameters update through a gradient descent process. The read threshold management component calculates predicted values using current weights, determines the difference from measured values, and adjusts the weights using a configurable learning rate parameter. This process allows the memory sub-system to learn individual die characteristics during normal operation

Between measurement intervals, the read threshold management component enters a prediction phase occurring at smaller time intervals θ. During prediction, the read threshold management component measures the reference voltage level and uses the updated weights to calculate appropriate read threshold voltages for other levels.

The read threshold management component supports flexible word line management through clustering capabilities. Within each die, word lines can be grouped into configurable clusters, with separate weight parameters maintained for each cluster. Rather than maintaining individual weight parameters for each of the hundreds of word lines in a die, the clustering approach reduces memory overhead while still capturing variations in behavior across different regions of the die. The processing device can determine the appropriate cluster for a given word line during operation and apply the corresponding weight parameters when calculating read threshold voltages. This clustering approach is particularly beneficial in large-scale systems with numerous dies, as it provides fine-grained control while maintaining reasonable memory requirements.

To ensure numerical stability, the system implements parameter scaling. Input voltage measurements are normalized to similar orders of magnitude before processing. This scaling enables reliable weight updates and consistent prediction accuracy.

The read threshold management techniques described herein automatically adapt to both die-to-die variations and program-erase count changes. The natural wear leveling of the memory sub-system distributes program-erase cycles across dies, allowing the weight parameters to evolve with device aging.

Memory efficiency improves through the elimination of lookup tables. Rather than storing multiple tables for different operating conditions, the memory sub-system maintains compact weight parameters that are used to calculate threshold voltages directly. This approach scales effectively with increasing die counts in large storage systems.

The read threshold management component supports both batch and incremental update modes. Batch updates process multiple measurement pairs simultaneously, while incremental updates handle individual pairs. This flexibility allows implementation choices based on available system resources.

This approach to read threshold management is applicable across different multi-level cell configurations. While certain examples provided herein reference TLC devices with eight voltage levels, the approach extends to Quad-Level Cell (QLC) or other configurations with different numbers of levels. The reference and target voltage levels remain configurable rather than fixed to specific level combinations.

By dynamically updating weight parameters for individual dies during system operation, this approach to read threshold management eliminates the need for static lookup tables while automatically compensating for both die-to-die variations and program-erase count changes. This approach significantly reduces memory overhead compared to traditional methods, particularly in large-scale systems with numerous dies, while enabling continuous adaptation to changing device characteristics. Through flexible word line clustering and support for both batch and incremental updates, this approach balances control granularity with resource efficiency across different implementation scenarios. A gradient descent learning mechanism leverages natural wear leveling to adapt parameters over time without requiring comprehensive factory characterization of individual dies, providing a memory-efficient solution that scales effectively with increasing system complexity while maintaining prediction accuracy.

FIG. 1 illustrates an example computing environment 100 that includes a memory sub-system 110, in accordance with some embodiments of the present disclosure.

The memory sub-system 110 can include media, such as one or more volatile memory devices (e.g., memory device 140), one or more non-volatile memory devices (e.g., memory device 130), or a combination of such.

A memory sub-system 110 can be a memory device, a memory module, or a hybrid of a memory device and memory module. Examples of a memory device include an SSD, a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, and so forth.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a USB interface, a Fibre Channel interface, a Serial Attached SCSI (SAS) interface, etc. The physical host interface can be used to transmit data between the host system 120 and the memory sub-system 110. The host system 120 can further utilize a Non-Volatile Memory Express (NVMe) interface to access the memory devices 130 and 140 when the memory sub-system 110 is coupled with the host system 120 by the PCIe or CXL interface. The physical host interface can provide an interface for passing control, address, data, and other signals between the memory sub-system 110 and the host system 120.

The memory devices can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

An example of non-volatile memory devices (e.g., memory device 130) includes a NAND type flash memory. Each of the memory devices 130 can include one or more arrays of memory cells such as single level cells (SLCs) and multi-level cells (MLCs) (e.g., TLCs, or QLCs). In some embodiments, a particular memory component can include an SLC portion, and an MLC portion, a TLC portion, or a QLC portion of memory cells. Each of the memory cells can store one or more bits of data used by the host system 120. Furthermore, the memory cells of the memory devices 130 can be grouped as memory pages or memory blocks that can refer to a unit of the memory component used to store data.

Although non-volatile memory components such as NAND type flash memory are described, the memory device 130 can be based on any other type of non-volatile memory, such as read-only memory (ROM), phase change memory (PCM), magneto random access memory (MRAM), NOR flash memory, electrically erasable programmable read-only memory (EEPROM), and a cross-point array of non-volatile memory cells. A cross-point array of non-volatile memory can perform bit storage based on a change of bulk resistance in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

A memory sub-system controller 115 can communicate with the memory devices 130 to perform operations such as reading data, writing data, or erasing data at the memory devices 130 and at other such operations. The memory sub-system controller 115 can include hardware such as one or more integrated circuits and/or discrete components, a buffer memory, or a combination thereof. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, and the like. The local memory 119 can also include ROM for storing micro-code. While the example memory sub-system 110 in FIG. 1 has been illustrated as including the memory sub-system controller 115, in another embodiment of the present disclosure, a memory sub-system 110 may not include a memory sub-system controller 115, and may instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical block address and a physical block address that are associated with the memory devices 130. The memory sub-system controller 115 can further include host interface circuitry to communicate with the host system 120 via the physical host interface. The host interface circuitry can convert the commands received from the host system into command instructions to access the memory devices 130 and convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

The memory sub-system 110 also includes a read threshold management component 113 that is responsible for read voltage threshold management for the memory device 130. The read threshold management component 113 manages read voltage thresholds through dynamic learning techniques. The read threshold management component 113 obtains initial weight values for multiple dies and measures read levels (voltage levels) at periodic intervals. The read threshold management component 113 dynamically updates weight values for individual dies using an online learning algorithm based on measured voltage correlations between reference and target voltage levels. These weight values form a two-parameter matrix used by the read threshold management component 113 to calculate appropriate read threshold voltages without requiring lookup tables. Between measurement intervals, the read threshold management component 113 enters a prediction phase where it uses current weight values to calculate read threshold voltages for other levels. As the system operates, the read threshold management component 113 allows weight values to automatically adapt to both die-to-die variations and program-erase count changes through system wear leveling.

In some embodiments, the memory sub-system controller 115 includes at least a portion of the read threshold management component 113. For example, the memory sub-system controller 115 can include a processor 117 (processing device) configured to execute instructions stored in local memory 119 (e.g., firmware) for performing the operations described herein. In some embodiments, the read threshold management component 113 is part of the host system 120, an application, or an operating system.

In some embodiments, the memory devices 130 include local media controllers 135 that operate in conjunction with memory sub-system controller 115 to execute operations on one or more memory cells of the memory devices 130. In some examples, the local media controllers 135 include at least a portion of the read threshold management component 113. Further details regarding the read threshold management component 113 are discussed below.

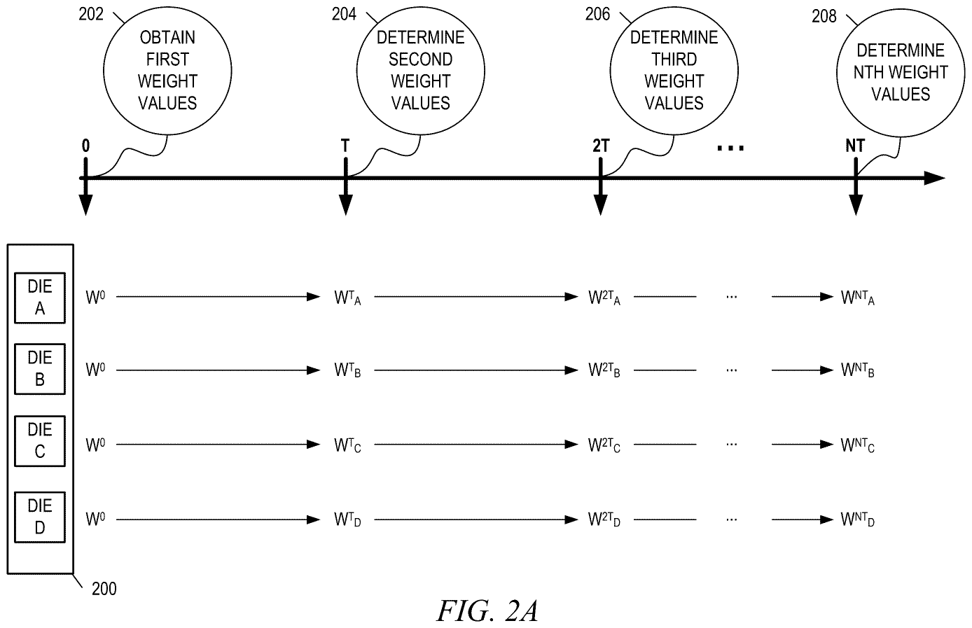

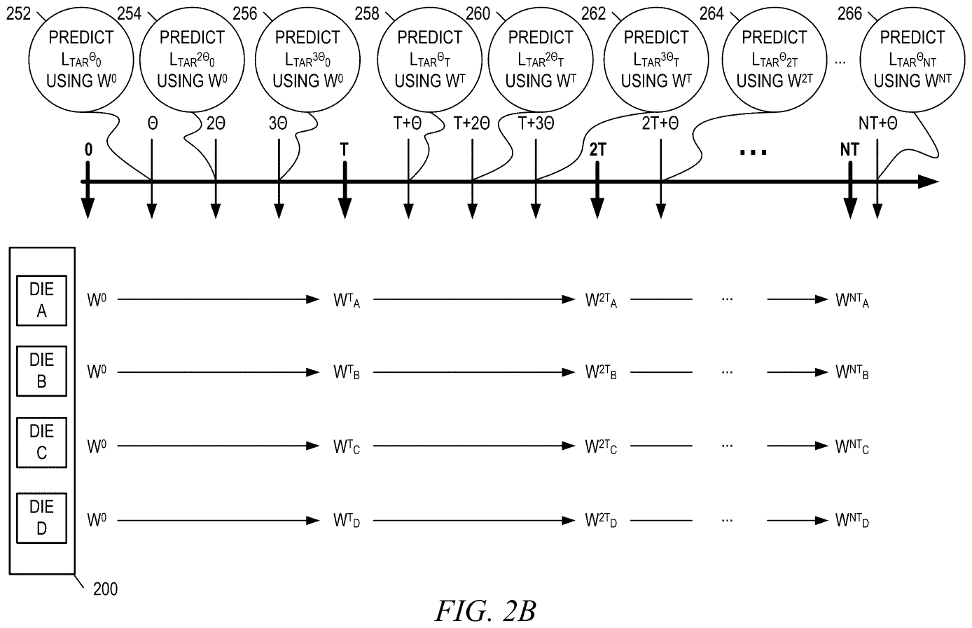

FIGS. 2A and 2B are conceptual diagrams illustrating an example process for read threshold management of a memory device 200, in accordance with some examples. More specifically, FIG. 2A illustrates a fitting (training) phase of the process while FIG. 2B illustrates a prediction phase of the process. Consistent with some examples, the process illustrated by FIGS. 2A and 2B is performed by the read threshold management component 113.

In the example illustrated in FIGS. 2A and 2B, the memory device 200 is an example memory device 130 in the example form of a NAND memory device. The memory device 200 includes multiple NAND dies such as Die A, Die B, Die C, and Die D illustrated in FIGS. 2A and 2B. Each NAND die may include one or more planes, and each plane includes multiple blocks. Each block includes a two-or three-dimensional array that includes pages (rows) and strings (columns). Pages in each block of the memory device 200 can be organized into multiple word line groups. A string includes a plurality of memory cells connected in series. Each memory cell is used to represent one or more bit values. For example, a single NAND flash cell includes a transistor that stores an electric charge on a memory layer that is isolated by oxide insulating layers above and below. Within each cell, data is stored as the threshold voltage of the transistor. SLC NAND, for example, can store one bit per cell. Other types of memory cells, such as MLCs, TLCs, QLCs, and PLCs, can store multiple bits per cell.

As noted above, each NAND cell comprises a transistor and stores data in the form of the threshold voltage (V_{T}) of the transistor. The range of threshold voltages of a memory cell can be divided into a number of regions based on the number of bits stored by the cell where each region corresponds to a value that can be represented by the cell. More specifically, each region corresponds to a read voltage level (also referred to simply as “read level”) and each read voltage level decodes into a multi-bit value. For example, a TLC NAND flash cell can be at one of eight read levels (L0, L1, L2, L3, L4, L5, L6, or L7) and each read level decodes into a 3-bit value that is stored in the flash cell (e.g., 111, 110, 100, 000, 010, 011, 001, and 101). Generally, to read data from a memory cell, one or more read threshold voltages are applied to the gate of a transistor (of the memory cell) to determine (e.g., sense) the value of the current V_{T} (e.g., the voltage at which the transistor conducts current), and the current V_{T} value can be decoded (e.g., mapped) to a data value (e.g., bit string) stored by the memory cell.

As NAND devices cycle through program and erase operations, the charge stored in memory cells gradually decreases due to charge loss effects, causing shifts in the V_{T} distributions. The V_{T} distributions for read levels tend to shift over time as charge is lost and thus, read level management is performed by the read level management component 113 to mitigate against these issues.

With reference to FIG. 2A, a timeline is illustrated to show periodic updates to a weight values for multiple dies of the memory device 200 at different time intervals. The weight values are used to predict read level values at various times. In an example, the weight values correspond to a two-parameter matrix W^{t} used to fit a linear equation to predict read levels.

In the context of the process illustrated by FIGS. 2A and 2B, the read threshold management component 113 predicts values for a target read level (“L_{TAR}”) based on W^{t} and measured values for a reference read level. Together, the target read level and the reference read level form a read level pair. In an example, the target read level is L3 and the reference read level is L7. Although only a single target read level is addressed by FIGS. 2A and 2B and the accompanying description, it shall be appreciated that the process is repeated for every read level such that values are predicted for all read levels using the same process. In repeating the process to predicted values for every read level, two or more read levels can be paired with the same reference read level in a read level pair or each read level may be paired with a different reference read level such that no two target read levels share the same reference read level.

In a first example, a first read level pair comprises a first target read level such as L3 and a reference read level such as L7 and a second read level pair comprises a second target read level such as L4 and the same reference read level (e.g., L7). Consistent with this example, measured values for the reference read level (e.g., L7) are used in conjunction with current weight values from W^{t} to predict values for both the first target read level (e.g., L3) and the second target read level (e.g., L4).

In a second example, a first read level pair comprises a first target read level such as L3 and a reference read level such as L7 and a second read level pair comprises a second target read level such as L4 and a second reference read level such as L6. Consistent with this example, measured values for the first reference read level (e.g., L7) are used in conjunction with current weight values from W^{t} to predict values for the first target read level (e.g., L3) and measured values for the second reference read level (e.g., L6) are used in conjunction with current weight values from W^{t} to predict values for the second target read level (e.g., L4).

The timeline shows time points 0, T, 2T, and NT, where T represents a time interval for weight updates. At time 0, the read threshold management component 113 obtains (initial) first weight values (W⁰) for all dies (Die A, Die B, Die C, and Die D) (operation 202). These initial weight values are the same across all dies. The initial weight values are determined during the manufacturing of the memory device 200 based on average behavior across all dies. In an example, these initial weight values are stored in the local memory 119, and the read threshold management component 113 obtains them by accessing them from local memory 119.

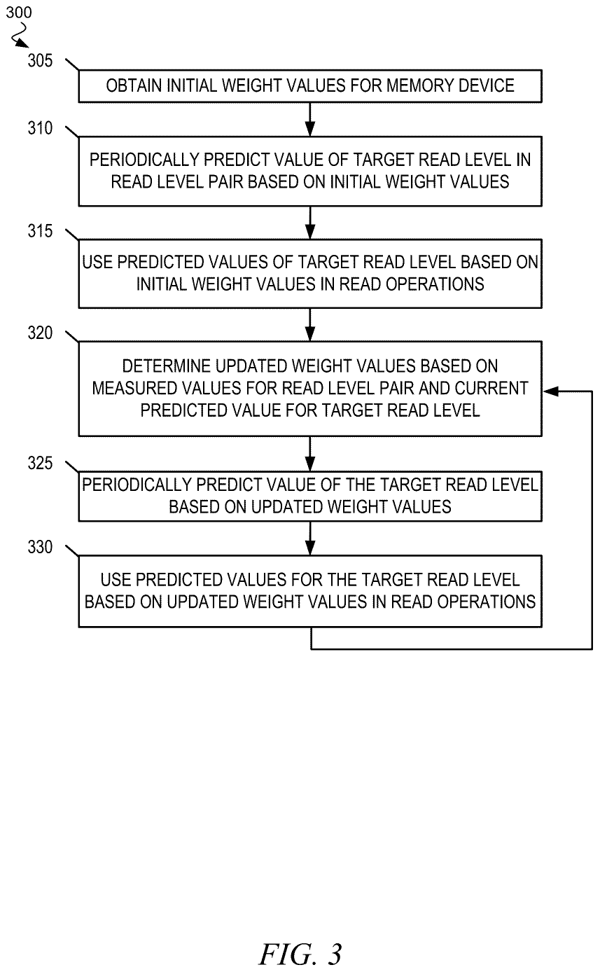

At time T, the read threshold management component 113 determines second weight values (W^{T}) independently for each die (at operation 204). That is, the read threshold management component 113 determines values for W^{T}_{A}, W^{T}_{B}, W^{T}_{C}, and W^{T}_{D}. At time 2T, the read threshold management component 113 determines third weight values (W^{2T}) for each die independently (operation 206). That is, the read threshold management components 113 determines values for W^{2T}_{A}, W^{2T}_{B}, W^{2T}_{C}, W^{2T}_{D}. As indicated by operation 208, which is performed at time NT, where the read threshold management component 113 determines Nth weight values W^{NT} (specifically values for W^{NT}_{A}, W^{NT}_{B}, W^{NT}_{C}, and W^{NT}_{D}), this pattern continues for the lifetime of the memory device 200. In updating the weight values, the read threshold management component 113 obtains measured values of the read level pair and uses the measured values to adjust the weight values. Further details regarding the updating of weight values are discussed below in reference to FIGS. 3-5.

In some examples, the initial weight values (W⁰) are stored in the local memory 119 and accessed by the read threshold component 113 to perform read level value predictions until the weight values are updated. As the process continues and the read threshold management component 113 updates the weight values at time intervals T, the updated weight values (W^{T}, W^{2T}, etc.) are stored in the local memory 119, replacing the previous weight values, in some examples, or are stored in a designated memory location in memory device 130 for each die, in other examples. For example systems that support word line clustering, the local memory 119 also stores separate weight values for each word line cluster within each die, organized in a manner that allows efficient retrieval based on the die identifier and cluster identifier. During prediction phases occurring at smaller time intervals θ, the processor 117 retrieves the current weight values from the local memory 119 to calculate the predicted values for target read voltage levels. This storage approach eliminates the need for lookup tables used in traditional methods, resulting in more efficient memory utilization as the system scales with increasing die counts.

The read threshold management component 113 supports both batch and incremental update modes to accommodate different system resource constraints. In batch update mode, the read threshold management component 113 processes multiple measurement pairs simultaneously, collecting several data points before performing weight updates. This approach can provide more stable updates by considering a broader set of measurements but requires additional memory to store these measurement pairs temporarily. Conversely, in incremental update mode, the read threshold management component 113 processes individual measurement pairs as they become available, immediately updating the weight parameters after each measurement. This approach minimizes memory requirements as only the current weight parameters need to be stored, making it particularly suitable for memory-constrained environments or large-scale systems with numerous dies. The read threshold management component 113 can be configured to use either update mode based on available resources and performance requirements, providing flexibility in implementation across different memory sub-system configurations.

FIG. 2B illustrates a prediction phase that occurs between the weight update intervals shown in FIG. 2A. With reference to FIG. 2B, the timeline includes the same time points 0, T, 2T, and NT, but also includes smaller time intervals represented by Θ (where Θ is smaller than T) where target read level values are predicted. Although FIG. 2B illustrates a particular number of prediction intervals Θ fitting between intervals T, it shall be appreciated that this a non-limiting example, and in other examples, additional or fewer prediction intervals Θ can be used.

As shown by operations 252, 254 and 256, between time 0 and time T, the read threshold management component 113 periodically predicts target read level values using the initial weight values W⁰ at interval Θ. More specifically, the operation 252 performed at time Θ includes predicting a first value for the target read level (L_{TAR}_{^{Θ}}₀); the operation 254 performed at 2Θ includes predicting a second value for the target read level (L_{TAR}_{^{2Θ}}₀); and the operation 256 performed at 3Θ includes predicting a third value for the target read level (L_{TAR}_{^{3Θ}}₀).

Between time T and time 2T, the read threshold management component 113 uses the second (updated) weight values W^{T} to predict target read level values, as shown by operations 258, 260, and 262, which represent predictions at times T+Θ, T+2Θ, and T+3Θ, respectively. More specifically, the operation 258 performed at time Θ includes predicting a fourth value for the target read level (L_{TAR}_{^{Θ}}_{T}); the operation 260 performed at 2Θ includes predicting a fifth value for the target read level (L_{TAR} 2Θ _{T}); and the operation 262 performed at 3Θ includes predicting a sixth value for the target read level (L_{TAR}_{^{3Θ}}_{T}).

After time 2T, the read threshold management component 113 uses the third weight values W^{2T} to predict target read level values, as shown by operation 264, wherein the read threshold management component 113 predicts a seventh value for the target read level (L_{TAR}_{^{Θ}}_{2T}) at time 2T+Θ.

The foregoing pattern of the prediction phase continues for the lifetime of the memory device 200, as indicated by operation 266 performed at time NT+Θ where the read threshold management component 113 uses the Nth weight values W^{NT} to predict an Nth value for the target read level (L_{TAR}_{^{Θ}}_{NT}). Further details regarding the prediction of target read level values are discussed below in reference to FIGS. 3-5.

The read threshold management process illustrated by FIGS. 2A and 2B is not limited to die-level management and can be further extended to support word line clustering within each die, as referenced above. That is, in some examples, the read threshold management component 113 can maintain separate weight values for different word line clusters within each die. Each die may contain hundreds of word lines that can be organized into configurable clusters based on similar behavioral characteristics. The read threshold management component 113 can maintain distinct weight values for each word line cluster, allowing for more granular read threshold management. For example, in a die with 280 word lines, these word lines could be grouped into multiple clusters (e.g., 10 clusters), with each cluster having its own set of weight values that are adjusted independently over time. This approach allows the read threshold management component 113 to capture variations in behavior not only between different dies but also between different regions within the same die. Consistent with these examples, during the fitting phase illustrated by FIG. 2A, the read threshold management component 113 obtains measurement pairs and updates weight values for each word line cluster separately. Similarly, during the prediction phase illustrated by FIG. 2B, the read threshold management component 113 uses the appropriate cluster-specific weight values to calculate predicted values for target read levels for the corresponding word line cluster(s). This word line clustering approach provides finer control granularity while maintaining memory efficiency by avoiding the need to store separate weight values for every individual word line.

In some examples, to ensure numerical stability during the fitting phase illustrated by FIG. 2A, the read threshold management component 113 implements parameter scaling for read level voltage measurements. Before processing, the read threshold management component 113 scales input voltage measurements to similar orders of magnitude, particularly when there are significant differences between reference and target read voltage levels. For example, when Level 7 measurements might be in the range of −70 to −20 DAC units while Level 3 measurements range from −12.5 to 0 DAC units, the read threshold management component 113 scales the Level 7 measurements to bring them closer to the range of Level 3 measurements. This scaling prevents numerical instability during gradient descent operations when updating weight values. Without proper scaling, the learning algorithm may become unstable or fail to converge properly when input values have vastly different magnitudes. The scaling parameters are stored alongside the weight values in the local memory 119 and are applied consistently during both the fitting and prediction phases to maintain accuracy in the read threshold voltage calculations.

FIG. 3 is a flow diagram illustrating an example method 300 for performing read threshold management on a memory device, in accordance with some examples. The method 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some embodiments, the method 300 is performed by the read threshold management component 113 of FIG. 1. Although processes are shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment; other process flows are possible.

At operation 305, the processing device obtains initial (first) values for weight W^{t} for a memory device (also referred to herein as “weight values”). In an example, the weight W^{t} is a two-parameter matrix used to fit a linear equation to predict read levels. In some examples, the initial weight values (W⁰) are stored in local memory (e.g., local memory 119) and the processing device obtains the initial weight values (W⁰) by accessing them from local memory. The processing device may use the initial weight values to initialize a separate weight matrix W^{t} for multiple portions of the memory device. In a first example, the processing device may create and store a separate weight matrix W^{t} in the local memory 119 for each die of the memory device. In a second example, the processing device may create and store multiple weight matrices W^{t} in the local memory 119, each of which corresponds to a word line cluster or grouping of word line clusters.

At operation 310, the processing device periodically predicts a value of a target read level in a read level pair for a portion of the memory device (e.g., a particular die, word line cluster, or word line cluster grouping) based on the initial weight values. The read level pair comprises the target read level and a reference read level. In an example, L7 is the reference read level and L3 is the target read level. The processing device updates the predicted value for the target read level at a time interval θ.

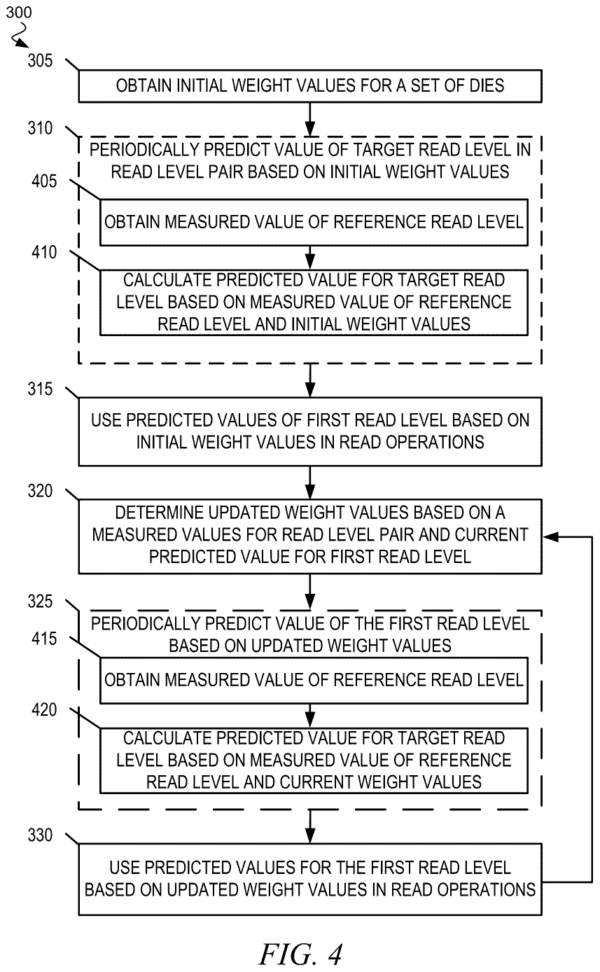

As shown in FIG. 4, in an example, determining a predicted value for the target read level of the portion of the memory device (at operation 310) includes obtaining a measured value of the reference read level for the portion of the memory device (operation 405) and calculating the predicted value for the target read level for the portion of the memory device based on the measured value of the reference read level and the initial weight values (operation 410). Consistent with this example, the processing device calculates the predicted value for the target read level by fitting a linear equation using the initial weight value. For example, the processing device may use the following linear equation to calculate a predicted value for a target read level:

LTar_{Pred}=a(LRef_{Meas})+B

where LTar_{Pred} is the predicted value for the target read level, LRef_{Meas} is the measured value of the reference read level, and a and b are the parameters of W^{t}.

With returned reference to FIG. 3, the processing device uses the predicted values for the target read level in performing one or more read operations on the portion (e.g., die, word line cluster, or word line cluster grouping) of the memory device, at operation 315. For example, the processing device may configure a read threshold voltage based on a current predicted target read level (e.g., by applying an appropriate offset to a default read threshold voltage).

The processing device continues to use the initial weight values to update the predicted value for the target read level for the portion of the memory device at interval θ until the processing device determines updated weight values (W^{T}) for the portion of the memory device, at operation 320. The processing device uses the initial weight values (W⁰) for the memory device to calculate predicted values for the target read level for the portion of the memory device for a time period T, after which the processing device updates the weight values for the portion of the memory device. The processing device determines updated weight values (W^{T}) for the portion of the memory device based on measured values for the read level pair for the portion of the memory device and a current predicted value for the target read level for the portion of the memory device. The processing device replaces previously stored weight values in local memory 119 with the updated weight values (W^{T}) for the portion of the memory device.

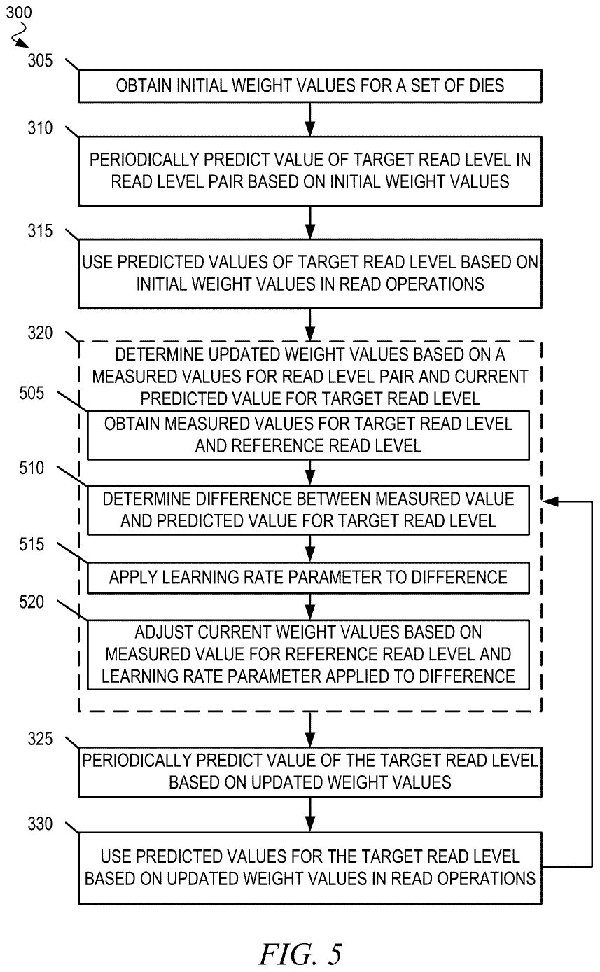

As shown in FIG. 5, in an example, determining updated weight values includes: obtaining a measured value for the target read level and a measured value for the reference read level for the portion of the memory device (operation 505), determining a difference between the measured value and a current predicted value for the target read level for the portion of the memory device (operation 510), applying a learning rate parameter to the difference (operation 515), and adjusting the current weight values for the portion of the memory device based on the measured value for the reference read level and the learning rate parameter applied to the difference (operation 520). For example, the processing device may determine updated weight values as follows:

W^{t+1}=W^{t}−η(LTar_{Pred}−LTar_{Meas})[LRef_{Meas}, 1]

where W^{t+1} is the updated weight, W^{t} is the current weight, η is the learning rate parameter, LTar_{Pred} is the current predicted value for the target read level, LTar_{Meas} is the measured value for the target read level obtained at operation 505, and LRef_{Meas} is the measured value for the reference read level obtained at operation 505.

The learning rate parameter η serves as a control mechanism in the weight update process, determining how quickly the learning algorithm adapts to new measurements. In some examples, this parameter is set to a small value between 0 and 1, such as 0.01, to ensure stable convergence. When applying the learning rate to the difference between predicted and measured values, a smaller learning rate results in more gradual weight adjustments, providing stability but requiring more iterations to adapt to changes. Conversely, a larger learning rate enables faster adaptation but may lead to oscillations or overshooting optimal values. The learning rate can be configured based on system characteristics and an expected rate of change in device behavior. The processing device can store different learning rates for different portions of the memory device (e.g., different dies or different word line groups), potentially using higher rates for newer devices to provide faster initial adaptation and lower rates for more stable, aged devices.

With returned reference to FIG. 3, the processing device periodically, at interval θ, predicts the value of the target read level for the portion of the memory device based on the updated weight values W^{T} for the portion of the memory device, at operation 325.

As shown in FIG. 4, in an example, the determining of a predicted value for the target read level based on updated (second) weight values W^{T} (at operation 325) includes obtaining a measured value of the reference read level (operation 415) for the portion of the memory device and calculating the predicted value for the target read level based on the measured value of the reference read level and the updated weight values W^{T} for the portion of the memory device (operation 420). Consistent with this example, the processing device may calculate a predicted value for the target reference value by using the updated weight values W^{T} (a and b) to fit the linear equation discussed above in reference to operation 310 to calculate the predicted value for the target read level.

With returned reference to FIG. 3, the processing device uses the predicted values of the target read level based on the updated weight values (W^{T}) in read operations (operation 330) on the portion of the memory device. That is, in performing a read operation, the processing device uses the current predicted value for the target read level in performing read operations. For example, as mentioned above, the processing device configures a read threshold voltage used in performing read operations on the portion of the memory device based on the current predicted value for the target read level.

The processing device uses the current updated weight values W^{T} for the portion of the memory device to determine, at interval θ, predicted values for the target read level, which are used in read operations, for the time period T, after which the method 300 returns to operation 320 where the weight values are updated once again (e.g., resulting in W^{2T} and W^{3T}, W^{4T} etc., in subsequent iterations of the method 300). That is, from time 0 to T, the processing device uses first (initial) weight values (W⁰) for the memory device to periodically predict the value (e.g., a first value) for the target read level, at interval θ; from time T to 2T the processing device uses second (updated) weight values (W^{T}) for the portion of the memory device to periodically predict the value (e.g., a second value) of the target read level, at interval θ; from time 2T to 3T the processing device uses third weight values (W^{2T}) for the portion of the memory device to periodically predict the value (e.g., a third value) of the target read level, at interval θ; and so forth.

Described implementations of the subject matter can include one or more features, alone or in combination, as illustrated below by way of example.

Example 1. A memory sub-system comprising: a memory device; a processing device, operatively coupled with the memory device, to perform operations comprising: obtaining initial weight values for the memory device; periodically calculating predicted values for a target read voltage level for a portion of the memory device based on the initial weight values, the calculating of the predicted values comprising calculating a predicted value for the target read voltage level based on the initial weight values and a first measured value for a reference read voltage level of the portion of the memory device; and periodically updating weight values for the portion of the memory device, the updating of the weight values comprising determining updated weight values for the portion of the memory device based on the initial weight values, a measured value for the target read voltage level, a second measured value for the reference read voltage level, and the predicted value for the target read voltage level.

Example 2. The memory sub-system of Example 2, wherein: calculating the predicted value for the target read voltage level comprises obtaining, at a first time, the measured value for target read level; and determining the updated weight values comprises obtaining, at a second time, the measured value for the target read voltage level and the second measured value for the reference read voltage level.

Example 3. The memory sub-system of any one or more of Examples 1 or 2, wherein the operations comprise using the predicted value for the target read voltage level to perform one or more read operations on the portion of the memory device.

Example 4. The memory sub-system of any one or more of Examples 1-3, wherein: the measured value for the target read voltage level is a first measured value for the target read voltage level; the predicted value for the target read voltage level is a first predicted value for the target read voltage level; the updated weight values for the portion of the memory device are second weight values for the portion; the operations comprise: after determining updated weight values, periodically calculating predicted values for the target read voltage based on the updated weight values, the periodic calculating of the predicted values comprising calculating a second predicted value for the target read voltage level for the portion of the memory device; and determining third weight values for the portion of the memory device based on the second weight values, a second measured value for the target read level voltage, a third measured value for the reference read level voltage, and the second predicted value for the first read voltage level.

Example 5. The memory sub-system of any one or more of Examples 1-4, wherein: the first measured value for the reference read voltage level is obtained at a first time; the first measured value for the target read voltage level and the second measured value for the reference read voltage level are obtained at a second time; the second predicted value for the target read voltage level is calculated at a third time; and the second measured value for the target read level voltage and the third measured value for the reference read level voltage are obtained at a fourth time.

Example 6. The memory sub-system of any one or more of Examples 1-5, wherein: the portion is a first portion; the operations comprise: calculating a predicted value for a second target read voltage level for a second portion of the memory device based on the initial weight values; and determining updated weight values for the second portion of the memory device based on the initial weight values, the predicted value for the second read voltage level, and measured values for a read level pair, the read level pair comprising the second read voltage level and a second reference read voltage level.

Example 7. The memory sub-system of any one or more of Examples 1-6, wherein: the target read voltage level is a first target read voltage level; and the operations comprise periodically calculating predicted values for a second target read voltage level for the portion of the memory device based on the initial weight values, the calculating of the predicted values comprising calculating a predicted value for the second target read voltage level based on the initial weight values and the first measured value for the reference read voltage level of the portion of the memory device.

Example 8. The memory sub-system of any one or more of Examples 1-7, wherein: the target read voltage level is a first target read voltage level; the reference read voltage level is a first reference read voltage level; and the operations comprise periodically calculating predicted values for a second target read voltage level for the portion of the memory device based on the initial weight values, the calculating of the predicted values comprising calculating a predicted value for the second target read voltage level based on the initial weight values and a measured value for a second reference read voltage level of the portion of the memory device.

Example 9. The memory sub-system of any one or more of Examples 1-8, wherein the determining updated weight values for the portion of the memory device comprises: determining a difference between the measured value for the target read voltage level and the predicted value for the target read voltage level; and adjusting the initial weight values based on the difference.

Example 10. The memory sub-system of any one or more of Examples 1-9, wherein the adjusting of the initial weight values comprises applying a learning rate parameter to the determined difference.

Example 11. The memory sub-system of any one or more of Examples 1-10, wherein the initial weight values correspond to a two-parameter weight matrix for fitting a linear equation.

Example 12. The memory sub-system of any one or more of Examples 1-11, wherein calculating the predicted value for the target read level voltage comprises fitting the linear equation with the weight values.

Example 13. The memory sub-system of any one or more of Examples 1-12, wherein: the calculating of the predicted values for the target read voltage level is performed at a first time interval; the updating of the weight values is performed at a second time interval; the first time interval is less than the second time interval.

Example 14. The memory sub-system of any one or more of Examples 1-13, wherein: the memory device comprises a set of dies; and the portion of the memory device is a die in the set of dies.

Example 15. The memory sub-system of any one or more of Examples 1-14, wherein: the memory device comprises a set of word line clusters; and the portion of the memory device is a word line cluster in the set of word line clusters.

Example 16. A method comprising: obtaining, by a processing device, initial weight values for a memory device, the initial weight values corresponding to a two-parameter matrix for fitting a linear equation; periodically calculating, by the processing device, predicted values for a target read voltage level for a portion of the memory device based on the initial weight values, the calculating of the predicted values comprising calculating a predicted value for the target read voltage level based on the initial weight values and a first measured value for a reference read voltage level of the memory device, the calculating of the predicted value for the target read voltage comprising fitting the linear equation with the initial weight values; and periodically updating, by the processing device, weight values for the portion of the memory device, the updating of the weight values comprising determining updated weight values for the portion of the memory device based on the initial weight values, a measured value for the target read voltage level, a second measured value for the reference read voltage level, and the predicted value for the target read voltage level.

Example 17. The method of Example 16, wherein: calculating the predicted value for the target read voltage level comprises obtaining, at a first time, the measured value for target read level; and determining the updated weight values comprises obtaining, at a second time, the measured value for the target read voltage level and the second measured value for the reference read voltage level.

Example 18. The method of any one or more of Examples 16 or 17, comprising using the predicted value for the target read voltage level to perform one or more read operations on the portion of the memory device.

Example 19. The method of any one or more of Examples 16-18, wherein the determining updated weight values for the portion of the memory device comprises: determining a difference between the measured value for the target read voltage level and the predicted value for the target read voltage level; and applying a learning rate parameter to the difference; and adjusting the initial weight values based on the learning rate parameter applied difference.

Example 20. A computer-readable storage medium comprising instructions that, when executed by a processing device, configure the processing device to perform operations comprising: obtaining, by a processing device, initial weight values for a memory device; periodically calculating, at a first time interval, predicted values for a target read voltage level for a portion of the memory device based on the initial weight values, the calculating of the predicted values comprising calculating a predicted value for the target read voltage level based on the initial weight values and a first measured value for a reference read voltage level of the portion of the memory device; and periodically updating, at a second time interval, weight values for the portion of the memory device, the updating of the weight values comprising determining updated weight values for the portion of the memory device based on the initial weight values, a measured value for the target read voltage level, a second measured value for the reference read voltage level, and the predicted value for the target read voltage level.

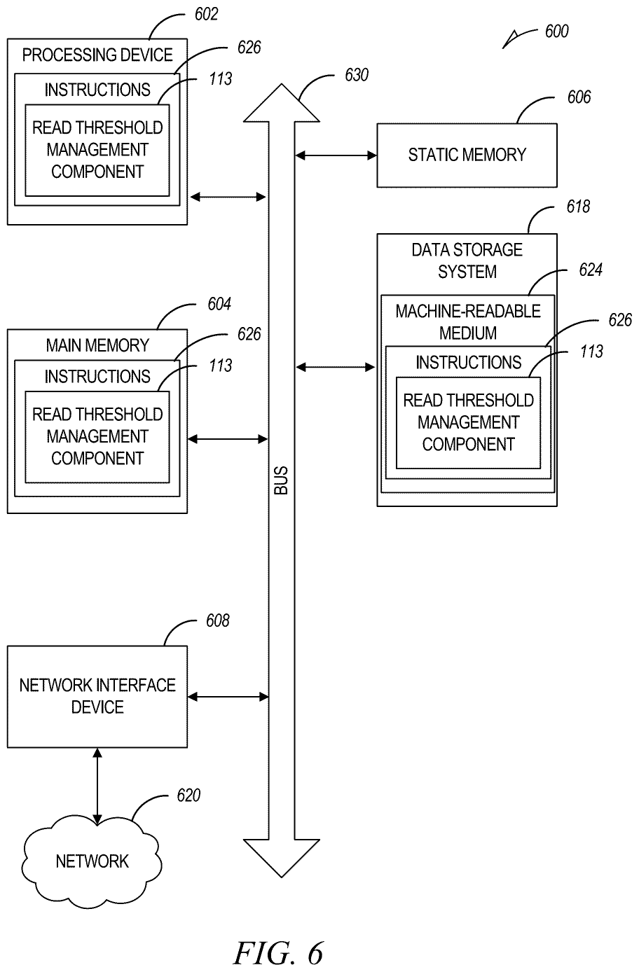

FIG. 6 illustrates an example machine in the form of a computer system within which a set of instructions can be executed for causing the machine to perform any one or more of the methodologies discussed herein. FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the read threshold management component 113 of FIG. 1). In alternative embodiments, the machine can be connected (e.g., networked) to other machines in a local area network (LAN), an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., ROM, flash memory, DRAM such as SDRAM or RDRAM, etc.), a static memory 606 (e.g., flash memory, static random-access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an ASIC, a FPGA, a digital signal processor (DSP), network processor, or the like. The processing device 602 is configured to execute instructions 626 for performing the operations and steps discussed herein. The computer system 600 can further include a network interface device 608 to communicate over a network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 include instructions to implement functionality corresponding to a read threshold management component (e.g., the read threshold management component 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, etc.

In the foregoing specification, embodiments of the disclosure have been described with reference to specific example embodiments thereof. It will be evident that various modifications can be made thereto without departing from the broader scope of embodiments of the disclosure as set forth in the following claims. The specification and drawings are, accordingly, to be regarded in an illustrative sense rather than a restrictive sense.

What is claimed is:

1. A memory sub-system comprising:
a memory device;
a processing device, operatively coupled with the memory device, to perform operations comprising:
obtaining initial weight values for the memory device;
periodically calculating predicted values for a target read voltage level for a portion of the memory device based on the initial weight values, the calculating of the predicted values comprising calculating a predicted value for the target read voltage level based on the initial weight values and a first measured value for a reference read voltage level of the portion of the memory device; and
periodically updating weight values for the portion of the memory device, the updating of the weight values comprising determining updated weight values for the portion of the memory device based on the initial weight values, a measured value for the target read voltage level, a second measured value for the reference read voltage level, and the predicted value for the target read voltage level.

2. The memory sub-system of claim 1, wherein:
calculating the predicted value for the target read voltage level comprises obtaining, at a first time, the measured value for target read level; and
determining the updated weight values comprises obtaining, at a second time, the measured value for the target read voltage level and the second measured value for the reference read voltage level.

3. The memory sub-system of claim 1, wherein the operations comprise using the predicted value for the target read voltage level to perform one or more read operations on the portion of the memory device.

4. The memory sub-system of claim 1, wherein:
the measured value for the target read voltage level is a first measured value for the target read voltage level;
the predicted value for the target read voltage level is a first predicted value for the target read voltage level;
the updated weight values for the portion of the memory device are second weight values for the portion;
the operations comprise:
after determining updated weight values, periodically calculating predicted values for the target read voltage based on the updated weight values, the periodic calculating of the predicted values comprising calculating a second predicted value for the target read voltage level for the portion of the memory device; and
determining third weight values for the portion of the memory device based on the second weight values, a second measured value for the target read level voltage, a third measured value for the reference read level voltage, and the second predicted value for the first read voltage level.

5. The memory sub-system of claim 4, wherein:
the first measured value for the reference read voltage level is obtained at a first time;
the first measured value for the target read voltage level and the second measured value for the reference read voltage level are obtained at a second time;
the second predicted value for the target read voltage level is calculated at a third time; and
the second measured value for the target read level voltage and the third measured value for the reference read level voltage are obtained at a fourth time.

6. The memory sub-system of claim 1, wherein:
the portion is a first portion;
the operations comprise:
calculating a predicted value for a second target read voltage level for a second portion of the memory device based on the initial weight values; and
determining updated weight values for the second portion of the memory device based on the initial weight values, the predicted value for the second read voltage level, and measured values for a read level pair, the read level pair comprising the second read voltage level and a second reference read voltage level.

7. The memory sub-system of claim 1, wherein:
the target read voltage level is a first target read voltage level; and
the operations comprise periodically calculating predicted values for a second target read voltage level for the portion of the memory device based on the initial weight values, the calculating of the predicted values comprising calculating a predicted value for the second target read voltage level based on the initial weight values and the first measured value for the reference read voltage level of the portion of the memory device.

8. The memory sub-system of claim 1, wherein:
the target read voltage level is a first target read voltage level;
the reference read voltage level is a first reference read voltage level; and
the operations comprise periodically calculating predicted values for a second target read voltage level for the portion of the memory device based on the initial weight values, the calculating of the predicted values comprising calculating a predicted value for the second target read voltage level based on the initial weight values and a measured value for a second reference read voltage level of the portion of the memory device.

9. The memory sub-system of claim 1, wherein the determining updated weight values for the portion of the memory device comprises:
determining a difference between the measured value for the target read voltage level and the predicted value for the target read voltage level; and
adjusting the initial weight values based on the difference.

10. The memory sub-system of claim 9, wherein the adjusting of the initial weight values comprises applying a learning rate parameter to the determined difference.

11. The memory sub-system of claim 1, wherein the initial weight values correspond to a two-parameter weight matrix for fitting a linear equation.

12. The memory sub-system of claim 11, wherein calculating the predicted value for the target read level voltage comprises fitting the linear equation with the weight values.

13. The memory sub-system of claim 1, wherein:
the calculating of the predicted values for the target read voltage level is performed at a first time interval;
the updating of the weight values is performed at a second time interval;
the first time interval is less than the second time interval.

14. The memory sub-system of claim 1, wherein: the memory device comprises a set of dies; and the portion of the memory device is a die in the set of dies.

15. The memory sub-system of claim 1, wherein: the memory device comprises a set of word line clusters; and the portion of the memory device is a word line cluster in the set of word line clusters.

16. A method comprising:
obtaining, by a processing device, initial weight values for a memory device, the initial weight values corresponding to a two-parameter matrix for fitting a linear equation;
periodically calculating, by the processing device, predicted values for a target read voltage level for a portion of the memory device based on the initial weight values, the calculating of the predicted values comprising calculating a predicted value for the target read voltage level based on the initial weight values and a first measured value for a reference read voltage level of the memory device, the calculating of the predicted value for the target read voltage comprising fitting the linear equation with the initial weight values; and
periodically updating, by the processing device, weight values for the portion of the memory device, the updating of the weight values comprising determining updated weight values for the portion of the memory device based on the initial weight values, a measured value for the target read voltage level, a second measured value for the reference read voltage level, and the predicted value for the target read voltage level.

17. The method of claim 16, wherein:
calculating the predicted value for the target read voltage level comprises obtaining, at a first time, the measured value for target read level; and
determining the updated weight values comprises obtaining, at a second time, the measured value for the target read voltage level and the second measured value for the reference read voltage level.

18. The method of claim 16, comprising using the predicted value for the target read voltage level to perform one or more read operations on the portion of the memory device.

19. The method of claim 16, wherein the determining updated weight values for the portion of the memory device comprises:
determining a difference between the measured value for the target read voltage level and the predicted value for the target read voltage level; and
applying a learning rate parameter to the difference; and
adjusting the initial weight values based on the learning rate parameter applied difference.

20. A computer-readable storage medium comprising instructions that, when executed by a processing device, configure the processing device to perform operations comprising:
obtaining, by a processing device, initial weight values for a memory device;
periodically calculating, at a first time interval, predicted values for a target read voltage level for a portion of the memory device based on the initial weight values, the calculating of the predicted values comprising calculating a predicted value for the target read voltage level based on the initial weight values and a first measured value for a reference read voltage level of the portion of the memory device; and
periodically updating, at a second time interval, weight values for the portion of the memory device, the updating of the weight values comprising determining updated weight values for the portion of the memory device based on the initial weight values, a measured value for the target read voltage level, a second measured value for the reference read voltage level, and the predicted value for the target read voltage level.
